(19) United States
(12) Patent Application Publication
(10) Pub. No.: US 2016/0254210 A1
(43) Pub. Date: Sep. 1, 2016

(54) SUPPORT FOR ELECTRONIC POWER COMPONENTS, POWER MODULE PROVIDED WITH SUCH A SUPPORT, AND CORRESPONDING PRODUCTION METHOD

(71) Applicants: GRISET, Neuilly Sur Seine (FR); LABORATOIRE NATIONAL DE METROLOGIE ET D'ESSAIS, Paris Cedex 1 (FR); Association pour la recherche et le developpment des methodes et processus industriels (A.R.M.I.N.E, Paris Cedex 6 (FR)

(72) Inventors: Jonathan Idrac, Montesson (FR); Abderrahmen Kaabi, Paris (FR); Yves Bienvenu, Evry (FR); Bertrand Pierre, Vaureal (FR)

(73) Assignees: GRISET, Neuilly Sur Seine (FR); LABORATOIRE NATIONAL DE METROLOGIE ET D'ESSAIS, Paris Cedex 1 (FR); Association pour la recherche et le developpment des methodes et processus industriels (A.R.M.I.N.E, Paris Ceddex 6 (FR)

(21) Appl. No.: 15/030,286

(22) PCT Filed: Oct. 18, 2013
(86) PCT No.: PCT/FR2013/052493

§ 371 Date: Apr. 18, 2016

(51) Int. Cl. H01L 23/373; H01L 21/48; H01L 23/367

(52) U.S. Cl. CPC H01L 23/3735; H01L 23/3677; H01L 23/3736; H01L 21/4882

(57) ABSTRACT

This substrate for power electronic components comprises a colaminated multilayer composite material containing at least one internal layer (8) made of a material having a thermal expansion coefficient chosen depending on the expansion coefficient of said components, and external layers (6, 7) made of a thermally conductive material covering on either side said internal layer and connected together by wells (P) made of a thermally conductive material, said wells being arranged in the internal layer.

Each interior layer forms an insert localized in a zone for mounting the components so that the external layers extend laterally beyond the insert.

Generally, the invention relates to the field of power electronics, more particularly relates to a substrate for power electronic components.

The invention also relates to a power electronic module and to a process for manufacturing such a substrate. Power modules are electronic modules that are especially used to control high-power loads, for example to control electric motors.

Their use is tending to increase, for example on board aircraft or automotive vehicles.

Power electronic modules include power electronic components, in particular electronic chips, made of silicon or another semiconductor such as gallium nitride, silicon carbide, etc., which are mounted on a substrate that especially allows the components to be cooled.

One of the main sources of power electronic component failure is related to the difference between the thermal expansion of, on the one hand, the substrate, which is generally made of copper, and, on the other hand, of the electronic chip, the expansion coefficient of which is generally about a third of that of copper. The continuous increase in the power and operating frequency of electronic components has led to higher and higher thermal losses, which has increased the working temperature of the power electronic components and of the substrate. The different metallurgical nature of the substrate and component leads to a difference in their thermal behavior with respect to heat. Therefore, temperature increases generate considerable shear stresses in the bonding zone, which may cause degradation or even destruction of the chip/substrate assemblies.

For the silicon chip to operate correctly and for its longevity, it is essential to remove as much heat as possible. Although copper fully performs its function as a thermal conductor, its linear expansion coefficient is more than three times higher than that of silicon or other currently used semiconductors, which is disadvantageous for the chip/substrate bond.

Thus, a substrate should have both a good thermal and even electrical conductivity and a linear expansion coefficient that is low and similar to that of glass or silicon in the plane of the substrate. However, these two properties are naturally contradictory. Specifically, except for diamond, no material in the periodic classification of the elements combines these two properties of thermal conductivity and low expansion.

It is for this reason that other substrates have been developed.

Thus, it has been proposed to use substrates based on a metal matrix composite (MMC). For example, it has been proposed to use Al/SiC [2, 3, 6], Cu/SiC [5], Cu/diamond [1, 2, 4], Cu/C (fibers) [1, 3, 8], etc. The manufacture of these materials is very complex and associated with a high cost price. In general, the part produced must furthermore have the final dimensions of the substrate since machining is almost impossible, meaning that one-off manufacturing processes, which offer little return on investment due to their low productivity, must be used.

Colaminated substrates comprising two external layers made of a thermally conductive metal placed on either side of an internal layer made of a material having a low thermal dilatability are also employed. Examples of colaminated substrates have been produced from layers of Cu/Mo/Cu [2, 3, 7], Cu/Mo-Cu alloys/Cu [2, 3, 7] or Cu/low-expansion Fe-Ni alloys/Cu [9]. Although they have a low expansion coefficient, their thermal conductivity in the direction of heat removal is however unsatisfactory. Specifically, the internal layer forms a thermal barrier. Such is in particular the case, for example, for Invar®, the thermal conductivity of which is twenty times lower than that of copper.

It has also been proposed to use a multilayer composite material comprising an internal layer made of Invar® and external layers made of a thermally conductive material, for example of copper or a copper alloy, said external layers being placed either side of the interior layer and connected together by wells that are also made of a thermally conductive material and that are arranged in the internal layer, so as to generate thermal bridges allowing heat to be removed through the internal layer even though it has a low thermal expansion coefficient.

In this respect the reader may refer to document FR 09 56 865 which describes such a multilayer composite material.

Such a material is produced by colaminating the internal and external layers.

It has been observed that such a material, although it allows the best compromise to be obtained between thermal conductivity and linear expansion coefficient, nevertheless has a major drawback that disadvantages its use as a power electronic module substrate, especially in automobiles, in the railroad field, in the field of avionics and of industrial machines.

Specifically, although the high pressures exerted during the colamination, and the resulting plastic deformations, make it possible to obtain atomic bonds between those facing surfaces of the internal and external layers that lie parallel to the lamination plane, and to densify micro-asperities in the plane of contact of the sheets, the lateral surfaces of the holes produced in the internal layer in order to receive the thermal bridges, which lie parallel to the lamination forces, form weak points in the atomic bonds and the mechanical cohesion of the layers is liable to be weaker in these zones.

It has in particular been observed that the bond between an Invar® layer and the external copper layers is liable to be weaker in these zones.

The bond between the Invar® layer and the copper external layers is in particular liable to be broken in zones in which the substrate is intended to be bent. The existence of the thermal bridges is a stress singularity on the macroscopic scale and the lower quality of the solid-state bonding of the internal and external layers on the microscopic scale on the walls of the holes accentuates the local weakness during a bending operation.

However, most of the time production of a substrate for a power electronic module entails shaping, especially bending, the substrate in order to make provision for connection to electromechanical subassemblies. Such shaping operations are especially required to create electrical inputs or outputs for the power module, avoiding the need to mechanically connect or solder these inputs or outputs which, otherwise, would lead to additional non-negligible costs and the risk of electrical discontinuities.

The aim of the invention is to mitigate this drawback and to provide a substrate for power electronic components that is made from a colaminated multilayer composite material, this substrate having, over its entire area, a good thermal and electrical conductivity and, in zones intended to receive electronic chips, a linear expansion coefficient close to that of silicon or any other semiconductor, this substrate being usable over a wide temperature range and thus having a much longer lifetime than those of currently available substrates.

Another aim of the invention is to provide such a substrate that also guarantees cohesion between the layers of the multilayer material.

Therefore, the subject of the invention, according to a first aspect, is a substrate for power electronic components, comprising a colaminated multilayer composite material containing at least one internal layer made of a material having a thermal expansion coefficient chosen depending on the expansion coefficient of said components, and external layers made of a thermally conductive material covering on either side said internal layer and connected together by wells made of a thermally conductive material, said wells being arranged in the interior layer.

Each internal layer forms an insert localized in a zone for mounting the components so that the external layers extend laterally beyond the insert.

In other words, the thermal wells that extend between the thermally conductive external layers through the internal layer of low thermal expansion coefficient enable heat removal. However, the material of low thermal expansion coefficient and the wells of thermally conductive material are only placed under the electronic components so that, laterally, colamination of the external layers without the insert creates between these layers a mechanical bond that is sufficiently strong that the ability to bend and shape the substrate is preserved.

For example, the material of the internal layer is chosen from Invar®, low-expansion Fe-Ni alloys, molybdenum and its alloys, niobium and its alloys, and tungsten and its alloys.

According to another feature of the substrate according to the invention, the conductive material of the external layers and/or wells comprises at least one metal chosen from copper and its alloys, silver and its alloys, and aluminum and its alloys.

According to yet another feature of the substrate according to the invention, at least one of the external layers comprises at least one first zone, in which said layer extends laterally beyond an internal layer, having a first thickness and at least one second zone localized in a zone for mounting the components having a second thickness smaller than the first thickness.

For example, the external layers, which cover on either side the internal layer, each comprise zones having said first and second thicknesses.

As a variant, one of the external layers, which covers one of the faces of the internal layer, comprises zones having said first and second thicknesses, the other external layer being laminated and having a constant thickness.

For example, the bridges are periodically distributed in the material.

Provision may for example be made for the proportion of wells per unit area to be smaller than 35%.

The subject of the invention is also, according to a second aspect, a power module comprising a substrate and electronic power components mounted on the substrate in zones for mounting the components, the substrate comprising a colaminated multilayer composite material containing at least one internal layer made of a material having a thermal expansion coefficient chosen depending on the expansion coefficient of said components, and external layers made of a thermally conductive material covering on either side said internal layer and connected together by wells made of a thermally conductive material, said wells being arranged in the internal layer.

Each internal layer forms an insert localized only in the zone for mounting the components so that the external layers extend laterally beyond the insert.

According to another feature of this power module, the substrate comprises bending zones. In these bending zones, the external layers are colaminated without insert.

In other words, outside of the zones for mounting the components, the external layers are colaminated without insert.

Lastly, the subject of the invention is also, according to a third aspect, a process for manufacturing a substrate for power electronic components, comprising the following steps:
positioning a first layer of a material having a thermal expansion coefficient chosen depending on the thermal expansion coefficient of the components between external layers made of a thermally conductive material so that the first layer of material forms an insert localized in a zone for mounting the components and so that the external layers are connected together by wells made of a thermally conductive material, said wells being arranged in the first layer, and so that the external layers extend laterally beyond the insert; and
colaminating said internal layer and the external layers via passage through the gap of a rolling mill.

Other aims, features and advantages of the invention will become apparent on reading the following description that is given merely by way of nonlimiting example and with reference to the appended drawings, in which:

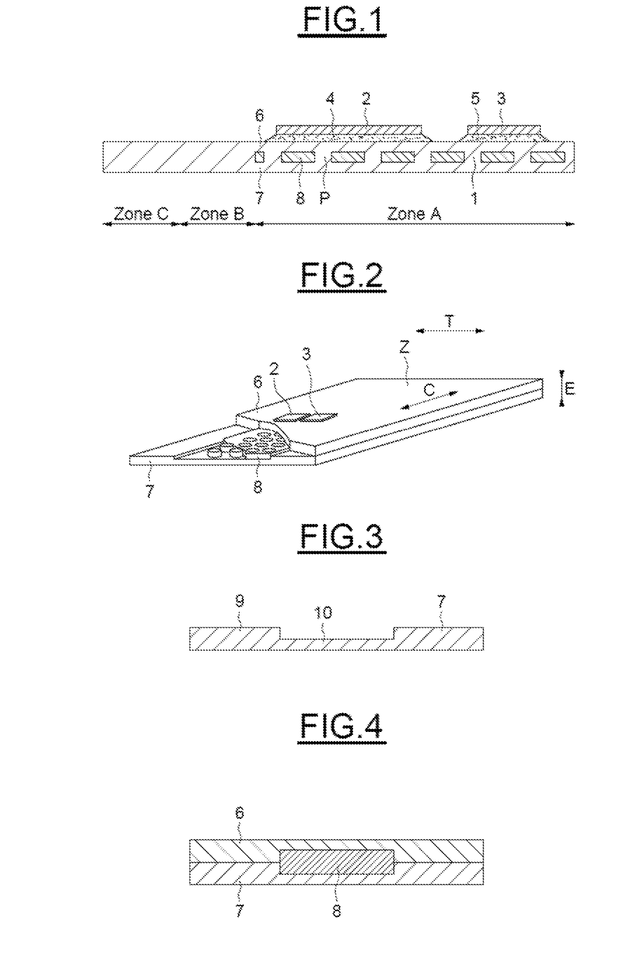

FIG. 1 is a cross-sectional view of a substrate according to the invention for a power electronic module;

FIG. 2 is a perspective view of the substrate in FIG. 1, with a partial cutaway;

FIGS. 3 and 4 illustrate one embodiment of a substrate according to the invention;

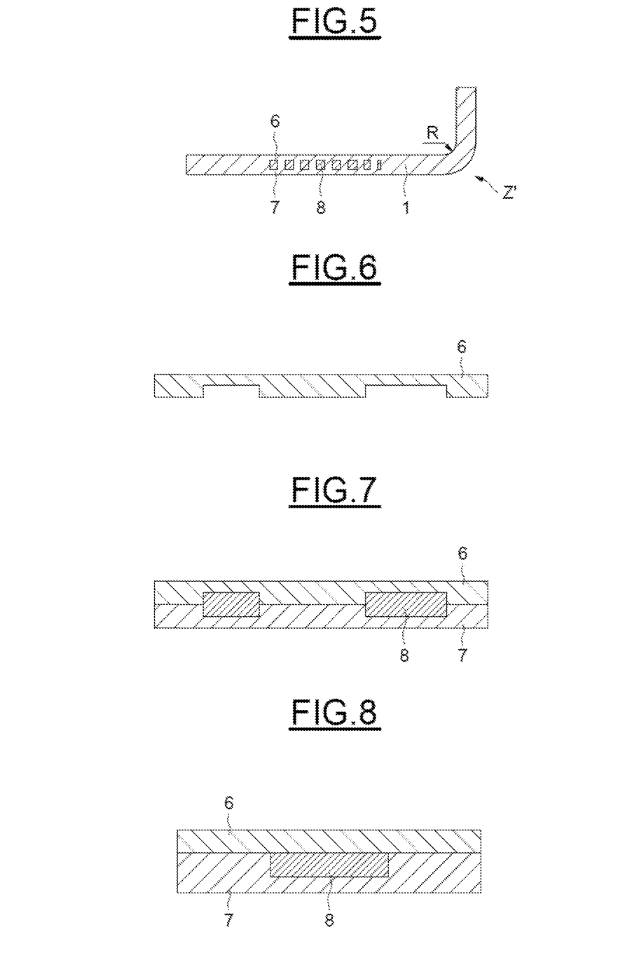

FIG. 5 schematically shows the substrate in FIG. 1 after bending;

FIGS. 6 and 7 illustrate another embodiment of a substrate according to the invention;

FIG. 8 illustrates a variant embodiment of a substrate according to the invention;

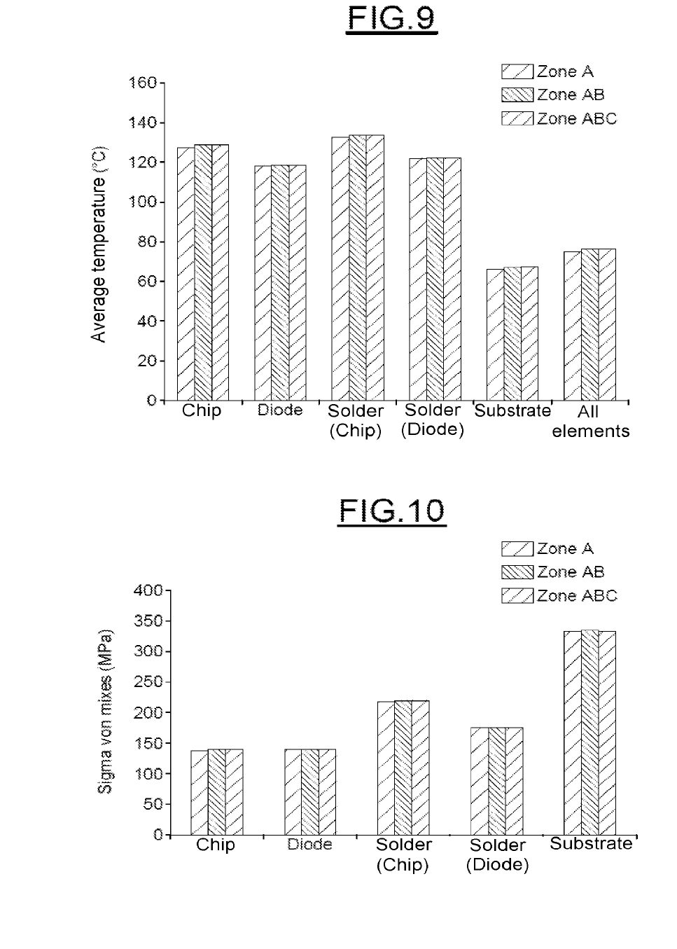

FIG. 9 is a histogram showing the temperature of various zones of a substrate according to the invention and according to the prior art and subjected to a severe thermal stress by the chips that it carries; and

FIG. 10 is a histogram showing the stress level in a substrate according to the invention and according to the prior art.

FIG. 1 shows a substrate according to the invention, designated by the general reference number 1.

The substrate is intended to form an element of a power electronic module, for example a power module comprising power electronic components 2 and 3, for example a transistor and a diode, respectively, mounted on the substrate 1 by means of a layer of solder 4 and 5.

As may be seen, the substrate 1 comprises two external layers 6 and 7 made of a conductive material, of metal in the present case, these layers being arranged on either side of an internal layer 8 made of a material having a low thermal dilatability.

The external layers 6 and 7 are preferably made of copper and thus provide excellent thermal and electrical conductivity in the plane of the layer and therefore ensure heat and current density are uniformly distributed.

The external layers 6, 7 may however also be made, as a variant, from a copper alloy, from silver or a silver alloy or from aluminum and its alloys.

The internal layer 8 for its part consists of a layer made of a material having a low thermal expansion, i.e. similar to that of silicon, so as to obtain a thermal expansion coefficient corresponding to that of the components 2 and 3 mounted on the substrate 1.

However, it may be seen that the internal layer 8 is perforated with channels forming wells P for rapidly conducting heat. These channels are filled with a material of very high thermal conductivity and thus form thermal bridges. This being the case, it will be understood that the material filling the channels locally replaces the material of the internal layer. In other words, the substrate comprises locally thermal bridges formed by the wells that extend between the external layers 6 and 7. Such wells, advantageously regularly distributed in the internal layer 8, may be obtained by perforating the internal layer or by machining, as will be described below. Nevertheless, it will be noted that, in one embodiment, the proportion of wells per unit area is advantageously smaller than 35%.

The thermal bridges will advantageously be made from the same material as that used to produce the external layers.

As regards the material used to produce the interior layer 8, it will be noted that it is possible to use molybdenum, niobium, etc. or a metal alloy having a low expansion such as Invar®.

Generally, these materials are well able to form a metallurgical bond with copper.

Molybdenum has thermomechanical properties suitable for the envisioned use. In particular it is a question of a high melting point, a high elastic modulus, a high mechanical strength at average temperature, good electrical and thermal conductivities, a low expansion coefficient and an excellent resistance to corrosion in many media. Other compositions based on Cu-Mo, such as colaminates (“Cu/Mo/Cu” and “Co/Mo₇₀Cu₃₀/Cu”) may also be used, also for such a mechatronic application as power module substrate.

Alternatively, as indicated above, it is possible to use Invar to produce the internal layer. It is a question of an FeNi_{(36%)} alloy associated with a very low thermal dilatability over a very wide range of temperatures extending from about −100° C. to +100° C. This alloy is used not only for this particular property but also for its mechanical characteristics.

However, as FIGS. 1 and 2 show, and especially FIG. 2 in which C, E and T designate the colamination direction, the thickness of the substrate and the transverse direction of the substrate, respectively, the internal layer is localized in the location of a zone Z for mounting the components 2 and 3. This being the case, this internal layer forms an insert localized only in this zone so that, laterally, i.e. on each side of the zone for mounting the components 2 and 3, the substrate comprises only the two colaminated external layers that, consequently, have atomic bonds that are sufficiently strong to allow the substrate to be bent.

With reference now to FIGS. 3 and 4, the substrate that has just been described is produced by colaminating external layers 6 and 7 and the localized internal layer 8.

First the exterior layers 6 or 7 are formed so as to obtain a layer having two thicknesses, i.e. comprising a first lateral zone 9, having a first thickness, which is intended to extend laterally beyond the internal layer, and a zone 10 having a second thickness smaller than the first thickness and intended to receive the internal layer 8.

It may be a question of carrying out a material removal step, for example by cutting, or of performing a hammering and/or rolling operation in the location of the second zone 10.

The layers 6 and 7 are then placed facing one another, with interposition of an internal layer 8, then the assembly is colaminated so as to obtain on either side of the thermal-bridge-containing zone a zone produced only from colaminated copper layers consequently permitting the substrate to be bent and in particular the substrate to be bent with a small radius R without damaging the solid-state bond produced by the colamination (FIG. 5).

In the example embodiment described with reference to FIGS. 3 and 4, the substrate comprises a single insert 8. Of course, the scope of the invention is not exceeded if the substrate comprises an array of such inserts (FIGS. 6 and 7).

Likewise, with reference to FIG. 8, in which elements that are identical to those in FIGS. 3 and 4 have been given the same references, it is also possible to produce a substrate from an external layer comprising the two zones 9 and 10 of different thicknesses so as to form imprints able to receive an insert made of a material having a thermal expansion coefficient chosen depending on the expansion coefficient of the electronic components, and a counter layer 7 produced by rolling and having a constant thickness.

As was described above, producing a substrate for power electronic components having an internal layer equipped with thermal bridges and localized in the location of the zone for mounting the components allows a good thermal and electrical conductivity and a linear expansion coefficient close to that of the components to be obtained. Furthermore, in the zone Z′ in which the substrate is intended to be bent, the substrate is devoid of inserts so that the external layers are colaminated, thereby allowing atomic bonds to be obtained that are sufficient to permit the substrate to be bent.

FIG. 9 shows the variation of the average temperature at various locations on the substrate in FIG. 1, especially in the location of the transistor chip 2, of the diode 3, level with the solder 4 of the chip 2, level with the solder 5 of the diode 3, level with the substrate 1 and for all of these elements. This histogram shows the temperature values in zone A in FIG. 1, i.e. under the components, the temperature values in zone B, neighboring zone A and the temperature values of a zone C laterally shifted from the zone B.

It will be observed that limiting the low expansion material to under the components does not modify the thermal behavior of the substrate.

Likewise, FIG. 10, which illustrates the variation of the Sigma von Mises stress in the zones A, B and C of the substrate, shows that no substantial modification of the mechanical behavior of the substrate is caused by localizing the low-dilation materials under the electronic components.

1. A substrate for power electronic components, comprising a colaminated multilayer composite material containing at least one internal layer (8) made of a material having a thermal expansion coefficient chosen depending on the expansion coefficient of said components, and external layers (6, 7) made of a thermally conductive material covering on either side said internal layer and connected together by wells (P) made of a thermally conductive material, said wells being arranged in the internal layer, characterized in that each internal layer forms an insert localized in a zone for mounting the components so that the exterior layers extend laterally beyond the insert.

2. The substrate as claimed in claim 1, in which the material of the internal layer is chosen from the group comprising Invar®, low-expansion Fe-Ni alloys, molybdenum and its alloys, niobium and its alloys, and tungsten and its alloys.

3. The substrate as claimed in claim 1, in which the conductive material of the external layers and/or wells comprises at least one metal chosen from copper and its alloys, silver and its alloys, and aluminum and its alloys.

4. The substrate as claimed in claim 1, in which at least one of the external layers comprises at least one first zone in which said layer extends laterally beyond an internal layer, having a first thickness and at least one second zone localized in a zone for mounting the component having a second thickness smaller than the first thickness.

5. The substrate as claimed in claim 4, in which the external layers that cover on either side the internal layer each comprise zones having said first and second thicknesses.

6. The substrate as claimed in claim 4, comprising an external layer that covers one of the faces of the internal layer and that comprises zones having said first and second thicknesses, and a laminated external layer having a constant thickness.

7. The substrate as claimed in claim 1, in which the wells are periodically distributed in the material.

8. The substrate as claimed in claim 1, in which the proportion of wells per unit area is smaller than 35%.

9. A power module comprising a substrate (1) and electronic power components (2, 3) mounted on the substrate in zones (Z) for mounting the components, the substrate comprising a colaminated multilayer composite material containing at least one internal layer (8) made of a material having a thermal expansion coefficient chosen depending on the expansion coefficient of said components, and external layers (6, 7) made of a thermally conductive material covering on either side said internal layer and connected together by wells (P) made of a thermally conductive material, said wells being arranged in the internal layer, characterized in that each interior layer forms an insert localized only in the zone for mounting the components so that the external layers extend laterally beyond the insert.

10. The module as claimed in claim 9, in which the substrate comprises bending zones (Z′) and in which in said bending zones the external layers are colaminated.

11. The module as claimed in claim 9, in which, outside of the zones for mounting the components, the external layers are colaminated.

12. A process for manufacturing a substrate for power electronic components, characterized in that it comprises the following steps:
positioning a first layer (8) of a material having a thermal expansion coefficient chosen depending on the thermal expansion coefficient of the components between external layers (6, 7) made of a thermally conductive material so that the first layer of material forms an insert localized in a zone (Z) for mounting the components and so that the external layers are connected together by wells made of a thermally conductive material, said wells being arranged in the first layer, and so that the external layers extend laterally beyond the insert; and
colaminating said internal layer and the external layers via passage through the gap of a rolling mill.
